(19) United States
(12) Patent Application Publication
(10) Pub. No.: US 2026/0190761 A1
(43) Pub. Date: Jul. 2, 2026

(54) DISPLAY DEVICE

(71) Applicant: LG Display Co., Ltd., Seoul (KR)

(72) Inventors: HwanKeon Lee, Gimpo-si (KR); Jungeun Lee, Seoul (KR); Jeongbeom Lee, Seoul (KR); Junhyeok Lee, Seoul (KR)

(73) Assignee: LG Display Co., Ltd., Seoul (KR)

(21) Appl. No.: 19/432,583

(22) Filed: Dec. 24, 2025

(30) Foreign Application Priority Data
Dec. 30, 2024 (KR) 10-2024-0199895

(51) Int. Cl. H10K 59/80; H10K 59/35; H10K 59/40; H10K 102/00

(52) U.S. Cl. CPC H10K 59/80521; H10K 59/35; H10K 59/40; H10K 59/873; H10K 59/8792; H10K 2102/351

(57) ABSTRACT

A display device includes a substrate on which a plurality of sub pixels are defined, a plurality of light emitting elements respectively disposed in the plurality of sub pixels on the substrate, and including an anode, a light emitting layer, and a first cathode respectively, a capping layer disposed on the first cathode of the plurality of light emitting elements, and having different thicknesses in at least one sub pixel of the plurality of sub pixels, and an organic dye layer disposed on the plurality of light emitting elements, wherein at least one of light emitting element among the plurality of light emitting elements further includes a second cathode disposed on the first cathode with the capping layer interposed therebetween.

### CROSS-REFERENCE TO RELATED APPLICATIONS

This application claims the priority of Koran Patent Application No. 10-2024-0199895 filed on Dec. 30, 2024, in the Korean Intellectual Property Office, the disclosure of which is incorporated herein by reference.

### BACKGROUND

### Technical Field

The present disclosure relates to a display device, and more particularly, to a display device capable of reducing reflection of external light.

### Discussion of the Related Art

As it enters the information age, the field of display devices that visually display electrical information signals is rapidly developing, and research is being conducted to develop performances such as thinning, weight reduction, and low power consumption for various display devices.

Representative display devices include a liquid crystal display (LCD) device, a field light emitting display (FED) device, an electro-wetting display (EWD) device, and an organic light emitting display (OLED) device.

An electroluminescent display device represented by an organic light emitting display device is a self-emitting display device and does not require a separate light source unlike a liquid crystal display device. Therefore, the electroluminescent display device can be manufactured to have a light weight and a small thickness. In addition, the electroluminescent display device is advantageous in terms of power consumption because the electroluminescent display device operates at a low voltage. Further, the electroluminescent display device is expected to be utilized in various fields because the electroluminescent display device is excellent in implementation of colors, response speeds, viewing angles, and contrast ratios (CRs).

### SUMMARY

Accordingly, embodiments of the present disclosure are directed to a display device that substantially obviates one or more of the problems due to limitations and disadvantages of the related art.

An aspect of the present disclosure is to provide a display device capable of reducing reflection of external light.

Another aspect of the present disclosure is to provide a display device capable of improving a black visibility when a display device does not emit light.

Still another aspect of the present disclosure is to provide a display device which reduces a process cost and a process time of the display device.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises a substrate on which a plurality of sub pixels including a first sub pixel, a second sub pixel, and a third sub pixel are defined, a plurality of light emitting elements respectively disposed in the first sub pixel, the second sub pixel and the third sub pixel on the substrate, and comprising a first light emitting element, a second light emitting element, and a third light emitting element including an anode, a light emitting layer, and a first cathode respectively, a capping layer disposed on the first cathode of the first light emitting element, the first cathode of the second light emitting element and the first cathode of the third light emitting element, and having different thicknesses in at least one sub pixel of the plurality of sub pixels, and a n organic dye layer disposed on the plurality of light emitting elements, wherein at least one of light emitting element among the plurality of light emitting elements further comprises a second cathode disposed on the first cathode with the capping layer interposed therebetween.

According to another aspect of the present disclosure, a display device comprises a substrate on which a plurality of sub pixels including a first sub pixel, a second sub pixel, and a third sub pixel is disposed, a plurality of light emitting elements including a first light emitting element, a second light emitting element and a third light emitting element, the first light emitting element, the second light emitting element and the third light emitting element being respectively disposed on the substrate in the first sub pixel, the second sub pixel, and the third sub pixel, and each of the first light emitting element, the second light emitting element and the third light emitting element including an anode, a light emitting layer, and a first cathode, and an organic dye layer disposed on the plurality of light emitting elements, a thickness of a capping layer disposed in any one of the plurality of sub pixels is greater than a thickness of the capping layer disposed in the other of the plurality of sub pixels.

Other detailed matters of the embodiments are included in the detailed description and the drawings.

In the display device of the present disclosure, when the display device does not emit light, reflectance of a green wavelength due to external light is increased, thereby improving a black visibility.

In the display device of the present disclosure, the mask process may be minimized or omitted by forming the organic dye layer by an application process such as inkjet or photo, thereby reducing process cost and process time and optimizing the process.

In the display device of the present disclosure, the organic dye layer integrated with the plurality of sub pixels is disposed between the first inorganic encapsulation layer and the second inorganic encapsulation layer instead of the organic encapsulation layer, thereby reducing the thickness of the display device and reducing the number of processes.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a block diagram illustrating a display device according to an exemplary embodiment of the present disclosure.

FIG. 2 is a view schematically illustrating a circuit configuration of a sub pixel according to an exemplary embodiment of the present disclosure.

FIG. 3 is a cross-sectional view taken along the line III-III′ of FIG. 1.

FIG. 4A is a diagram illustrating reflectance according to wavelength in the display devices according to Reference Examples 1 and 2.

FIG. 4B is a diagram illustrating reflectance according to wavelength in the display devices according to Examples and Comparative Examples.

FIG. 5 is a schematic cross-sectional view of a display device according to another embodiment of the present disclosure.

FIG. 6 is a schematic cross-sectional view of a display device according to still another exemplary embodiment of the present disclosure.

FIG. 7 is a schematic cross-sectional view of a display device according to still another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, the element or layer may be disposed directly on another element or layer, or the other element or layer may be interposed therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, exemplary embodiments of the present disclosure will be described in detail with reference to accompanying drawings.

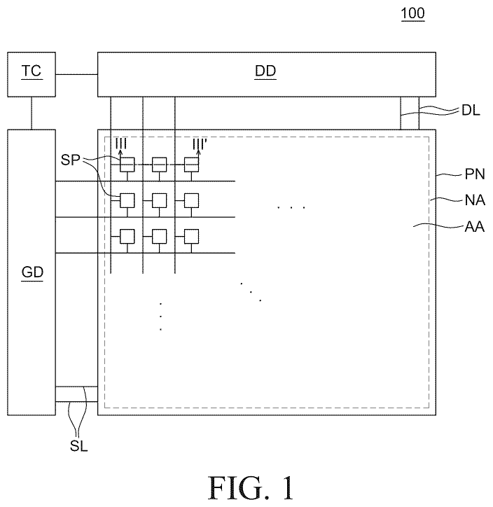

FIG. 1 is a block diagram illustrating a display device according to an exemplary embodiment of the present disclosure. FIG. 1 is a schematic block diagram of a display device according to an exemplary embodiment of the present disclosure. In FIG. 1, for the convenience of description, among various components of the display device 100, only a display panel PN, a gate driver GD, a data driver DD, and a timing controller TC are illustrated.

Referring to FIG. 1, a display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals provided from the timing controller TC. FIG. 1 illustrates that one gate driver GD is disposed to be spaced apart from one side of the display panel PN. However, the number and arrangement of the gate drivers GD are not limited thereto.

The data driver DD supplies a data voltage to a plurality of data lines DL according to a plurality of data control signals and image data provided from the timing controller TC. The data driver DD may convert image data into a data voltage using a reference gamma voltage and supply the converted data voltage to a plurality of data lines DL.

The timing controller TC aligns image data input from the outside and supplies the image data to the data driver DD. The timing controller TC may generate a gate control signal and a data control signal by using a synchronization signal input from the outside, for example, a dot clock signal, a data enable signal, and a horizontal/vertical synchronization signal. Further, the timing controller TC supplies the generated gate control signal and data control signal to the gate driver GD and the data driver DD, respectively, to control the gate driver GD and the data driver DD.

The display panel PN is configured to display images to a user and includes a plurality of sub pixels SP. In the display panel PN, the plurality of scan lines SL and the plurality of data lines DL may cross each other, and the plurality of sub pixels SP may be formed at intersections of the scan line SL and the data line DL.

In the display panel PN, a display area AA and a non-display area NA may be defined.

The display area AA is an area in which images are displayed in the display device 100. In the display area AA, a plurality of sub pixels SP constituting a plurality of pixels and a pixel circuit for driving the plurality of sub pixels SP may be disposed. The sub pixel SP is a minimum unit constituting the display area AA, and n sub pixels SP may form one pixel. In each of the plurality of sub pixels SP, a thin film transistor for driving the plurality of light emitting elements is disposed so that the plurality of sub pixels SP may independently emit light.

The plurality of light emitting elements may be differently defined depending on the type of the display panel PN. For example, when the display panel PN is an organic light emitting display panel, the light emitting element may be an organic light emitting element.

In the display area AA, a plurality of signal lines for transmitting various signals to the plurality of sub pixels SP is disposed. For example, the plurality of signal lines may include a plurality of data lines DL which supplies a data voltage to each of the plurality of sub pixels SP, a plurality of scan lines SL which supplies a scan signal to each of the plurality of sub pixels SP, and the like. The plurality of scan lines SL may extend in one direction in the display area AA and be connected to the plurality of sub pixels SP, and the plurality of data lines DL may extend in a direction different from the one direction in the display area AA and be connected to the plurality of sub pixels SP. In addition, in the display area AA, a low potential power line, a high potential power line, and the like may be further disposed, but are not limited thereto.

The non-display area NA is an area where an image is not displayed and may be defined as an area extending from the display area AA. In the non-display area NA, a link line and a pad electrode for transmitting a signal to the sub pixel SP of the display area AA, or a driving IC, such as a gate driver IC or a data driver IC, may be disposed.

Meanwhile, a driver such as a gate driver GD, a data driver DD, and a timing controller TC may be connected to the display panel PN in various ways. For example, the gate driver GD may be mounted in the non-display area NA in a gate-in-panel (GIP) manner or mounted between the plurality of sub pixels SP in the display area AA in a gate-in-active area (GIA) manner.

For example, the data driver DD and the timing controller TC are formed on separate flexible film and printed circuit board, and the display panel PN, the data driver DD, and the timing controller TC may be electrically connected by bonding the flexible film and the printed circuit board to the pad electrode formed in the non-display area NA of the display panel PN.

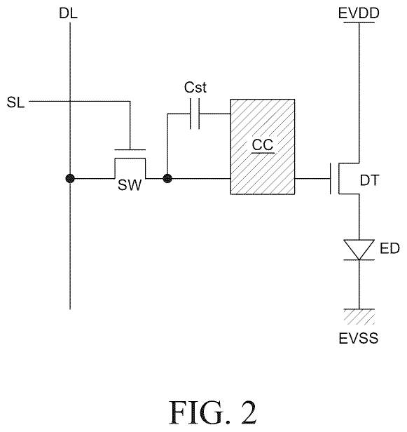

FIG. 2 is a view schematically illustrating a circuit configuration of a sub pixel according to an embodiment of the present disclosure.

Referring to FIG. 2, one sub pixel may include a switching transistor SW, a driving transistor DT, a capacitor Cst, a compensation circuit CC, and an organic light emitting element ED.

For example, the switching transistor SW may perform a switching operation so that a data signal supplied through the data line DL is stored in the capacitor Cst as a data voltage in response to a scan signal supplied through the scan line SL. Further, for example, the driving transistor DT may operate such that a driving current flows between the high potential power line EVDD and the low potential power line EVSS according to a data voltage stored in the capacitor Cst. Further, the organic light emitting element ED may operate to emit light according to a driving current formed by the driving transistor DT.

The compensation circuit CC is a circuit added to the sub pixel to compensate for a threshold voltage of the driving transistor DT. The compensation circuit CC may include one or more transistors. The configuration of the compensation circuit CC may vary depending on an external compensation method.

The sub pixel illustrated in FIG. 2 is configured by a 2T (transistor) 1C (capacitor) structure including a switching transistor ST, a driving transistor DT, a capacitor Cst, and a light emitting element ED. When the compensation circuit 135 is added, the sub pixel may be configured in various forms, such as 3T1C, 4T2C, 5T2C, 6T1C, 6T2C, 7T1C, and 7T2C.

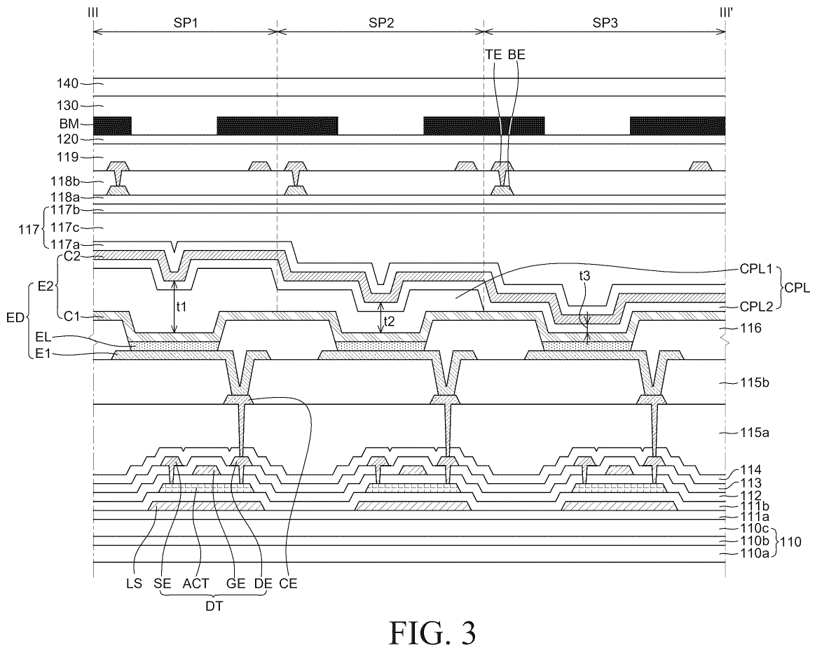

FIG. 3 is a cross-sectional view taken along the line III-III′ of FIG. 1. In FIG. 3, components included in a plurality of sub pixels SP disposed in the display area AA are shown for convenience of description.

The plurality of sub pixels SP may include a first sub pixel SP1, a second sub pixel SP2, and a third sub pixel SP3 which emit different color light. For example, the first sub pixel SP1 may be referred to as a red sub pixel SP1 as emitting red light, the second sub pixel SP2 may be referred to as a green sub pixel SP2 as emitting green light, and the third sub pixel SP3 may be referred to as a blue sub pixel SP3 emitting blue light, but it is not limited thereto.

A plurality of light emitting elements ED may be disposed in each of the plurality of sub pixels SP. For example, a first light emitting element may be disposed in the first sub pixel SP1, a second light emitting element may be disposed in the second sub pixel SP2, and a third light emitting element may be disposed in the third sub pixel SP3. The first light emitting element may be referred to as a red light emitting element, the second light emitting element may be referred to as a green light emitting element, and the third light emitting element may be referred to as a blue light emitting element, but is not limited thereto.

Referring to FIG. 3, the substrate 110 is a component for supporting various components included in the display device 100 and may be formed of an insulating material. The substrate 110 may include a first substrate 110a, a second substrate 110b, and an insulating layer 110c. The insulating layer 110c may be disposed between the first substrate 110a and the second substrate 110b. As described above, the substrate 110 is configured by the first substrate 110a, the second substrate 110b, and the insulating layer 110c to suppress moisture permeation. For example, the first substrate 110a and the second substrate 110b may be polyimide (PI) substrates.

The first buffer layer 111a is disposed on the substrate 110. The first buffer layer 111a may reduce permeation of moisture, oxygen, or impurities through the substrate 110. For example, the first buffer layer 111a may be configured as a single layer or multilayer made of silicon oxide (SiOx) or silicon nitride (SiNx). However, the present disclosure is not limited thereto.

The light shielding layer LS is disposed on the first buffer layer 111a in each of the plurality of sub pixels. The light shielding layer LS blocks light incident onto an active layer ACT of the driving transistor DT to be described below from a lower portion of the substrate 110. Light which is incident onto the active layer ACT of the driving transistor DT is blocked by the light shielding layer LS to minimize a leakage current.

The second buffer layer 111b is disposed on the substrate 110 and the light shielding layer LS. The second buffer layer 111b may reduce penetration of moisture or impurities through the substrate 110. For example, the second buffer layer 111b may be configured by a single layer or a double layer of silicon oxide (SiOx) or silicon nitride (SiNx), but is not limited thereto. However, the second buffer layer 111b may be omitted depending on the type of substrate 110 or the type of transistor, but is not limited thereto.

The driving transistor DT of each of the plurality of sub pixels SP is disposed on the second buffer layer 111b. The driving transistor DT is a transistor for controlling a driving current supplied to the light emitting element ED.

The driving transistor DT includes an active layer ACT, a gate electrode GE, a source electrode SE, and a drain electrode DE.

The active layer ACT of the driving transistor DT may be disposed on the second buffer layer 111b. For example, the active layer ACT may be formed of polysilicon (p-Si), amorphous silicon (a-Si), or an oxide semiconductor, but is not limited thereto.

The gate insulating layer 112 may be disposed on the active layer ACT. The gate insulating layer 112 is an insulating layer which insulates the active layer ACT from the gate electrode GE and may be formed of silicon oxide (SiOx), silicon nitride (SiNx), or a double layer thereof.

Further, the gate electrode GE of the driving transistor DT may be disposed on the gate insulating layer 112. The gate electrode GE is disposed on the gate insulating layer 112 so as to overlap the active layer ACT. The gate electrode GE may be formed of various conductive materials, such as magnesium (Mg), aluminum (Al), nickel (Ni), chromium (Cr), molybdenum (Mo), tungsten (W), gold (Au), or an alloy thereof, but is not limited thereto.

The interlayer insulating layer 113 may be disposed to cover the gate electrode GE. The interlayer insulating layer 113 is an insulating layer which protects components below the interlayer insulating layer 113 and may be configured by a single layer or a double layer of silicon oxide (SiOx) or silicon nitride (SiNx), but is not limited thereto.

The source electrode SE and the drain electrode DE of the driving transistor DT may be disposed on the interlayer insulating layer 113.

The source electrode SE and the drain electrode DE may be connected to one side and the other side of the active layer ACT, respectively, through contact holes provided in the interlayer insulating layer 113 and the gate insulating layer 112. The source electrode SE and the drain electrode DE may be formed of various conductive materials, such as magnesium (Mg), aluminum (Al), nickel (Ni), chromium (Cr), molybdenum (Mo), tungsten (W), gold (Au), or an alloy thereof, but are not limited thereto.

A portion of the active layer ACT overlapping the gate electrode GE is a channel region. One of the source electrode SE and the drain electrode DE is connected to one side of the channel region in the active layer ACT, and the other is connected to the other side of the channel region in the active layer ACT.

The passivation layer 114 may be disposed on the source electrode SE and the drain electrode DE. The passivation layer 114 is provided to protect the driving transistor DT and may be formed of an inorganic layer, for example, silicon oxide (SiOx), silicon nitride (SiNx), or a double layer thereof.

The first planarization layer 115a may be disposed on the passivation layer 114. The first planarization layer 115a may protect the driving transistor DT and planarize an upper portion thereof. The first planarization layer 115a may be configured by a single layer or a double layer, and for example, may be formed of photoresist or an acrylic organic material, but is not limited thereto.

The connection electrode CE may be disposed on the first planarization layer 115a.

The connection electrode CE may be connected to one of the source electrode SE and the drain electrode DE through a contact hole provided in the first planarization layer 115a.

The second planarization layer 115b may be disposed on the connection electrode CE. The second planarization layer 115b may be made of the same material as the first planarization layer 115a.

On the top of the second planarization layer 115b, the light emitting element ED including the first electrode E1, the organic layer EL, and the second electrode E2 may be disposed in each sub pixel SP.

Hereinafter, a stack structure of the light emitting element ED will be described in detail.

The first electrode E1 may be disposed on the second planarization layer 115b. For example, the first electrode E1 may be referred to as an anode. In this case, the first electrode E1 may be electrically connected to the connection electrode CE through a contact hole provided in the second planarization layer 115b. The first electrode E1 may be formed of a metallic material.

For example, when the display device 100 is a top light emitting type in which light emitted from the light emitting element ED is emitted above the substrate SUB on which the light emitting element ED is disposed, the first electrode E1 may include a transparent conductive layer and a reflective layer. The transparent conductive layer may be made of a transparent conductive oxide such as ITO or IZO, and the reflective layer may be made of, for example, silver (Ag), aluminum (Al), gold (Au), molybdenum (Mo), tungsten (W), chromium (Cr), or an alloy thereof.

The bank 116 may be disposed while covering the end of the first electrode E1 to define a light emitting area. A portion of the bank 116 corresponding to the light emitting area of the sub pixel SP may be opened. A part of the first electrode E1 may be exposed through the open part of the bank 116 (hereinafter, referred to as an open area). In this case, the bank 116 may be made of an inorganic insulating material, such as silicon nitride (SiNx) or silicon oxide (SiOx), or an organic insulating material, such as benzocyclobutene-based resin, acrylic-based resin, or imide-based resin, but is not limited thereto.

The bank 116 may be configured as a black bank including a light absorbing material. For example, in the bank 116, the light absorbing material may include carbon or black ink. The bank 116 may prevent light emitted from the light emitting element ED from being directed to a side surface, thereby preventing color mixture between adjacent sub pixels SP and preventing reflection of external light. In addition, the bank 116 may prevent external light reflection due to the reflective material disposed therebelow. Furthermore, even if the polarization layer is not disposed, the bank 116 may prevent a light leakage defect or the like.

The light emitting layer EL may be disposed on the bank 116. Accordingly, the light emitting layer EL may be disposed on the first electrode E1 exposed through the open area of the bank 116.

The light emitting layer EL is a layer for emitting light of a specific color and may have a structure separated for each sub pixel SP. The light emitting layer EL may include a plurality of organic material layers such as a hole transport layer, a hole injection layer, an electron transport layer, or an electron injection layer. For example, the light emitting layer EL disposed in the red sub pixel SP1 emitting red light may include a light emitting layer emitting red light, the light emitting layer EL disposed in the green sub pixel SP2 emitting green light may include a light emitting layer emitting green light, and the light emitting layer EL disposed in the blue sub pixel SP3 emitting blue light may include a light emitting layer emitting blue light. The light emitting layers EL disposed in the red sub pixel SP1, the green sub pixel SP2, and the blue sub pixel SP3 may be disposed to be separated from each other.

The second electrode E2 may be disposed on the light emitting layer EL and the bank 116. For example, the second electrode E2 may be referred to as a cathode. The second electrode E2 may include a first cathode C1 and a second cathode C2.

For example, the first cathode C1 may be disposed on the light emitting layer EL in each of the red sub pixel SP1, the green sub pixel SP2, and the blue sub pixel SP3.

The first cathode C1 may include a transparent conductive material that transmits light. For example, at least one of indium tin oxide (ITO) and indium zinc oxide (IZO) may be formed, but is not limited thereto. Alternatively, the first cathode C1 may include a semi-transmissive metal material that transmits light. For example, the first cathode C1 may be formed of at least one of bismuth (Bi), titanium (Ti), molybdenum (Mo), tungsten (W), silver (Ag), magnesium (Mg), aluminum (Al), platinum (Pt), palladium (Pd), gold (Au), nickel (Ni), neodymium (Nd), iridium (Ir), chromium (Cr), lithium (Li), and calcium (Ca), but is not limited thereto.

A capping layer CPL may be disposed between the first cathode C1 and the second cathode C2. The capping layer CPL may help light emitted from the light emitting layer EL to be efficiently emitted to the outside while protecting the light emitting element ED.

The capping layer CPL may include a first capping layer CPL1 and a second capping layer CPL2 disposed on the first capping layer CPL1 and made of a material different from that of the first capping layer CPL1.

The first capping layer CPL1 may be formed of an organic material, and the second capping layer CPL2 may be formed of an inorganic material.

The first capping layer CPL1 may include an organic material composed of at least one selected from the group consisting of NPD(N,N-dinaphthyl-N,N′-diphenylbenzidine), TPD(N,N′-bis-(3-methylphenyl)-N, N′-bis-(phenyl)-benzidine), s-TAD, MTDATA(4,4′,4-Tris(N-3-methylphenyl-N-phenyl-amino)-triphenylamine), Alq3(tris(8-hydroxyquinolino)aluminum), PBD(2-(4-biphenylyl)-5-(4-tert-butylpheny)-1,3,4oxadiazole), TAZ, spiro-PBD, BAlq, SAlq, CBP(carbazole biphenyl) and mCP(1,3-bis(carbazol-9-yl)benzene). However, the present disclosure is not limited thereto, the first capping layer CPL1 may be applied as long as it is the organic material that helps light emitted from the light emitting layer EL to be efficiently emitted to the outside while protecting the light emitting element ED.

The second capping layer CPL2 may include an inorganic materials composed of at least one selected from the group consisting of lithium fluoride (LiF), silicon oxide (SiOx), and silicon oxynitride (SiON), but is not limited thereto.

The first capping layer CPL1 made of an organic material and the second capping layer CPL2 made of an inorganic material may have different refractive indexes. For example, the refractive index of the first capping layer CPL1 may be greater than 1.8, for example, 1.9 to 2.1, and the refractive index of the second capping layer CPL2 may be less than 1.8, for example, 1.2 to 1.5.

The capping layer CPL may have a different thickness in at least one of the red sub pixel SP1, the green sub pixel SP2, and the blue sub pixel SP3.

The thickness of the capping layer CPL in each of the red sub pixel SP1, the green sub pixel SP2, and the blue sub pixel SP3 may be different by adjusting the thickness of the first capping layer CPL1 made of an organic material. For example, the first capping layer CPL1 having different thicknesses may be disposed in the red sub pixel SP1 and the green sub pixel SP2 using a mask process. Thereafter, in each of the red sub pixel SP1, the green sub pixel SP2, and the blue sub pixel SP3, the second capping layer CPL2 made of an inorganic material is disposed on the first capping layer CPL1 with the same thickness.

Referring to FIG. 3, a thickness t1 of the capping layer CPL in the red sub pixel SP1 may be thicker than a thickness t2 of the capping layer CPL in the green sub pixel SP2, and a thickness t2 of the capping layer CPL in the green sub pixel SP2 may be thicker than a thickness t3 of the capping layer CPL in the blue sub pixel SP3.

Since the capping layer CPL includes the first capping layer CPL1 and the second capping layer CPL2, the refractive index of the capping layer CPL in each of the red sub pixel SP1, the green sub pixel SP2, and the blue sub pixel SP3 may be adjusted to improve the light extraction efficiency.

The second cathode C2 may be disposed on the capping layer CPL in at least one of the red sub pixel SP1, the green sub pixel SP2, and the blue sub pixel SP3, for example, the second cathode C2 may be disposed on the capping layer CPL in each of the red sub pixel SP1, the green sub pixel SP2, and the blue sub pixel SP3.

For example, the second cathode C2 may include the same material as the first cathode C1.

The second electrode E2 includes a first cathode C1 and a second cathode C2. A capping layer CPL having a different thickness for each sub pixel SP is disposed between the first cathode C1 and the second cathode C2, resonance may be generated within the cavity formed by the firs cathode C1, the capping layer CPL, and the second cathode C2 for each sub pixel SP.

Resonance means that light of a specific wavelength is amplified by constructive interference by being repeatedly reflected between two layers separated by an optical length. For example, light incident on the second electrode E2 in each sub pixel SP is repeatedly reflected between the first cathode C1 and the second cathode C2 to cause constructive interference for a specific wavelength. Accordingly, the second electrode E2 including the first cathode C1 and the second cathode C2 may maximize the transmittance for light of a specific wavelength.

Since each color in each sub pixel SP has a different wavelength band, a resonance distance may be set for each wavelength band for a specific color in order to generate constructive interference for light of a specific color by implementing a resonance effect in the second electrode E2. For example, the resonance distance may be set by changing the thickness of the capping layer CPL.

For example, light in a wavelength band which does not correspond to the set resonance distance may be extinguished by extinction interference in the capping layer CPL.

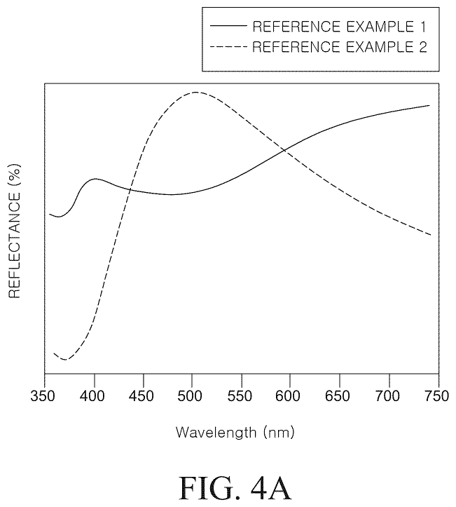

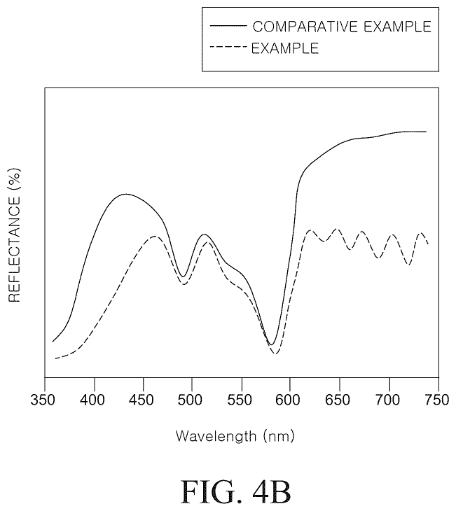

Further, when the second electrode E2 includes the first cathode C1 and the second cathode C2, extinction interference of light due to external light may occur at a specific wavelength due to resonance. The extinction interference of light due to external light will be described with reference to FIGS. 4A and 4B to be described later.

The encapsulation unit 117 may be located on the light emitting element ED described above.

The encapsulation unit 117 may have a single-layered structure or a multi-layered structure. For example, the encapsulation unit 117 may include a first inorganic encapsulation layer 117a, a second inorganic encapsulation layer 117b, and an organic encapsulation layer 117c.

For example, the organic encapsulation layer 117c among the first inorganic encapsulation layer 117a, the second inorganic encapsulation layer 117b, and the organic encapsulation layer 117c, is the thickest and may serve as a planarization layer.

The first inorganic encapsulation layer 117a may be disposed on the second electrode E2 and disposed to be most adjacent to the light emitting element ED. The first inorganic encapsulation layer 117a may be formed of an inorganic insulating material on which low-temperature deposition may be performed. For example, the first inorganic encapsulation layer 117a may be made of silicon nitride (SiNx), silicon oxide (SiOx), silicon oxynitride (SiON), or aluminum oxide (Al₂O₃). Since the first inorganic encapsulation layer 117a is deposited in a low temperature atmosphere, it is possible to prevent damage to the light emitting layer EL including an organic material vulnerable to a high temperature atmosphere during the deposition process. The organic encapsulation layer 117c may be formed to have a smaller area than the first inorganic encapsulation layer 117a. In this case, the organic encapsulation layer 117c may be formed to expose both ends of the first inorganic encapsulation layer 117a. The organic encapsulation layer 117c may serve as a buffer to alleviate stress between layers and to enhance planarization performance.

For example, the organic encapsulation layer 117c may be made of an organic insulating material such as acrylic resin, epoxy resin, polyimide, polyethylene, or silicon oxycarbon (SiOC). For example, the organic encapsulation layer 117c may be formed by an inkjet method, but is not limited thereto.

The second inorganic encapsulation layer 117b may be formed above the substrate 110 on which the organic encapsulation layer 117c is formed so as to cover upper surfaces and side surfaces of the first inorganic encapsulation layer 117a and the organic encapsulation layer 117c. In this case, the second inorganic encapsulation layer 117b may minimize or block the permeation of external moisture or oxygen into the first inorganic encapsulation layer 117a and the organic encapsulation layer 117c. For example, the second inorganic encapsulation layer 117b may be made of an inorganic insulating material such as silicon nitride (SiNx), silicon oxide (SiOx), silicon oxynitride (SiON), or aluminum oxide (Al₂O₃).

A touch sensing unit may be disposed on the encapsulation unit 117 described above.

Specifically, the touch sensing unit may include a touch buffer layer 118a disposed on the encapsulation unit 117, a bridge electrode BE disposed on the touch buffer layer 118a, a touch interlayer insulating layer 118b disposed on the touch buffer layer 118a and the bridge electrode BE, and a plurality of touch electrodes TE disposed on the touch interlayer insulating layer 118b.

The touch buffer layer 118a may block a chemical solution such as a developer or an etching solution used in the manufacturing process of touch electrodes formed on the touch buffer layer 118a or external moisture or foreign substances from penetrating into the light emitting element.

The plurality of touch electrodes TE may include a plurality of first touch electrodes extending in a first direction and a plurality of second touch electrodes extending in a second direction intersecting the first direction.

For example, the plurality of first touch electrodes and the plurality of second touch electrodes may be disposed on the same layer. However, in an area where the plurality of first touch electrodes and the plurality of second touch electrodes intersect, the plurality of second touch electrodes may be separately disposed, and the plurality of separated second touch electrodes may be connected by the bridge electrode BE. A touch interlayer insulating layer 118b may be disposed between the plurality of second touch electrodes and the bridge electrode BE.

The first protective layer 119 may be disposed to cover the touch sensing unit. The first protective layer 119 may be formed of an organic insulating layer. The first protective layer 119 may protect the touch sensing unit and planarize an upper portion thereof. Further, the step at the upper layer of the display device 100 is prevented by the first protective layer 119 to improve the visibility of the display device 100.

The third buffer layer 120 may be disposed on the first protective layer 119. The third buffer layer 120 may reduce the penetration of moisture, oxygen, or impurities through the upper portion of the display device 100. For example, the third buffer layer 120 may be configured by a single layer or a double layer of silicon oxide (SiOx) or silicon nitride (SiNx), but is not limited thereto.

A black matrix BM may be disposed on the third buffer layer 120. For example, the black matrix BM may be provided in an integrated mesh shape to correspond to the non-light emitting areas of the plurality of light emitting elements ED, but is not limited thereto. For example, the black matrix BM may be disposed to partially overlap the light emitting areas of the plurality of light emitting elements ED. In this case, reflectance may be improved, and front luminance may be improved due to a condensing effect.

The black matrix BM may include a light absorbing material that absorbs a visible light wavelength band. That is, the black matrix BM may be a kind of light blocking member. The black matrix BM may prevent external light reflection by the plurality of touch electrodes TE and the plurality of bridge electrodes BE. For example, the black matrix BM may be made of a material that may be processed at a low temperature of about 100° C. or less, preferably about 85° C. or less. When the black matrix BM is made of a material capable of a low-temperature process, thermal damage to the light emitting element ED due to the formation of the black matrix BM may be minimized.

The organic dye layer 130 may be disposed on the black matrix BM. For example, the organic dye layer 130 may include a colorant such as a dye or pigment and a monomer. Further, the organic dye layer 130 may further include a polymer material in addition to a colorant and a monomer. For example, when the organic dye layer 130 further includes a polymer material, a top surface of the organic dye layer 130 may be planarized. The polymer material included in the organic dye layer 130 may be a polyimide, epoxy, or acrylic polymer material, but is not limited thereto, and may be used without being limited as long as it is for planarizing the organic dye layer 130.

The organic dye layer 130 may be formed by an application process such as inkjet or photo. For example, when the organic dye layer 130 is applied by the inkjet method, the black matrix BM disposed at the outermost side of the display panel may serve as an inkjet process dam.

The organic dye layer 130 may be integrally disposed to cover the light emitting area and the non-light emitting area of the plurality of light emitting elements ED. Specifically, the organic dye layer 130 may be integrally formed to correspond to the red sub pixel SP1, the green sub pixel SP2, and the blue sub pixel SP3 to have a wavelength that transmits both red light, green light, and blue light. Accordingly, even though the plurality of light emitting elements ED disposed in each of the red sub pixel SP1, the green sub pixel SP2, and the blue sub pixel SP3 emits red light, green light, or blue light, the organic dye layer 130 may transmit light emitted from each of the plurality of sub pixels SP.

Further, the organic dye layer 130 is integrally formed to correspond to the plurality of sub pixels SP, thereby simplifying the manufacturing process and reducing the process cost and the process time compared to the case where the organic dye layer is separately formed for each sub pixel.

Meanwhile, the second protective layer 140 may be disposed to cover the organic dye layer 130. The second protective layer 140 may be formed of an organic insulating layer. It is possible to improve the visibility of the display device 100 by preventing a step on the uppermost layer of the display device 100 by the second protective layer 140.

FIG. 4A is a diagram illustrating reflectance according to wavelength in the display devices according to Reference Examples 1 and 2. FIG. 4B is a diagram illustrating reflectance according to wavelength in the display devices according to Examples and Comparative Examples. First, the Example of FIG. 4B is a display device according to the embodiment of the present disclosure, and the comparative example of FIG. 4B is a case in which the second cathode is omitted in the display device according to the embodiment of the present disclosure, that is, a capping layer is disposed on the first cathode, and an encapsulation unit is directly disposed on the capping layer. In addition, Reference Example 1 of FIG. 4A is a case where the organic dye layer is omitted in the Comparative Example of FIG. 4B, and Reference Example 2 of FIG. 4B is a case where the organic dye layer is omitted in the Example of FIG. 4B. FIG. 4A shows reflectance at each wavelength for external light for Reference Examples 1 and 2, and FIG. 4B shows reflectance for external light for Examples and Comparative Examples. In this case, a wavelength of about 620 nm to 740 nm may represent a red wavelength, about 510 nm to 600 nm may represent a green wavelength, and a wavelength of about 440 nm to 490 nm may represent a blue wavelength. First, referring to FIG. 4A together, in the case of Reference Example 1, the reflectance is relatively high at almost all wavelength ranges, whereas in Reference Example 2, the reflectance is lower than that of Reference Example 1 at red and blue wavelengths, but the reflectance is higher than that of Reference Example 1 only at green wavelengths.

Next, referring to FIG. 4B, in the case of the Example, it may be seen that the deviation of the reflectance according to each wavelength is reduced compared to the comparative example as the organic dye layer is added to the structure of Reference Example 2 in which the reflectance at the green wavelength is increased. That is, as compared with the comparative example, at the red wavelength and the blue wavelength, extinction interference caused by the first cathode C1 and the second cathode C2 occurs, thereby reducing reflectance at the red wavelength and the blue wavelength. However, the green wavelength may include reflectance equivalent to that of the comparative example. Accordingly, in the case of the embodiment, reflectance of red wavelength and blue wavelength is reduced due to extinction interference compared to the comparative example, so that reflectance of light of green wavelength may increase relatively. Accordingly, when the display device 100 does not emit light, as the reflectance of the green wavelength, which is a purple complementary color, caused by the organic dye layer 130 increases, when the display device 100 does not emit light, the display device 100 may be visually recognized as black by the user.

In general, a display device having a structure in which a polarization layer is attached to a display panel is used. However, when the polarization layer is separately attached, there is a problem that the thickness of the display device increases. To overcome this, a color filter is disposed in the display panel to replace the polarization layer. However, in this case, there is a problem in that a mask process for patterning the color filter is added as the color filter is disposed for each sub pixel, thereby increasing process cost and process time. Accordingly, instead of a color filter separated for each sub pixel in the display panel, an organic dye layer integrated into the plurality of sub pixels is disposed. However, in this case, when the display device does not emit light, the display device has a problem in that purple due to the organic dye layer is visually recognized by the user due to reflection of external light.

Accordingly, in the display device 100 according to the exemplary embodiment of the present disclosure, when the display device 100 does not emit light, the reflectance of the green wavelength, which has a complementary color relationship with the purple due to the organic dye layer 130, may be increased to improve the black visibility.

Specifically, the second cathode C2 is further disposed on the first cathode C1 with the capping layer CPL interposed in the green sub pixel SP2, so that when the display device 100 does not emit light, reflectance of the green wavelength due to external light may be increased. Accordingly, when the display device 100 does not emit light, the reflectance of the green wavelength, which has a complementary color relationship with the purple due to the organic dye layer 130, may increase, thereby improving the black visibility.

Further, in the display device 100 according to the exemplary embodiment of the present disclosure, the organic dye layer 130 integrated in the plurality of sub pixels SP is disposed by an application process such as inkjet or photo to reduce the thickness of the display device 100 and reduce process cost and process time by not performing a mask process.

Further, in the display device 100 according to the exemplary embodiment of the present disclosure, the low-temperature black matrix BM and the bank 116 are disposed in the non-light emitting area of the plurality of light emitting elements ED to suppress light emitted from the plurality of light emitting elements ED from being directed to the non-light emitting area of the plurality of light emitting elements ED. Accordingly, even if the polarization layer is not disposed, reflectance in the non-light emitting area of the plurality of light emitting elements ED may be reduced, and light leakage defects may be prevented.

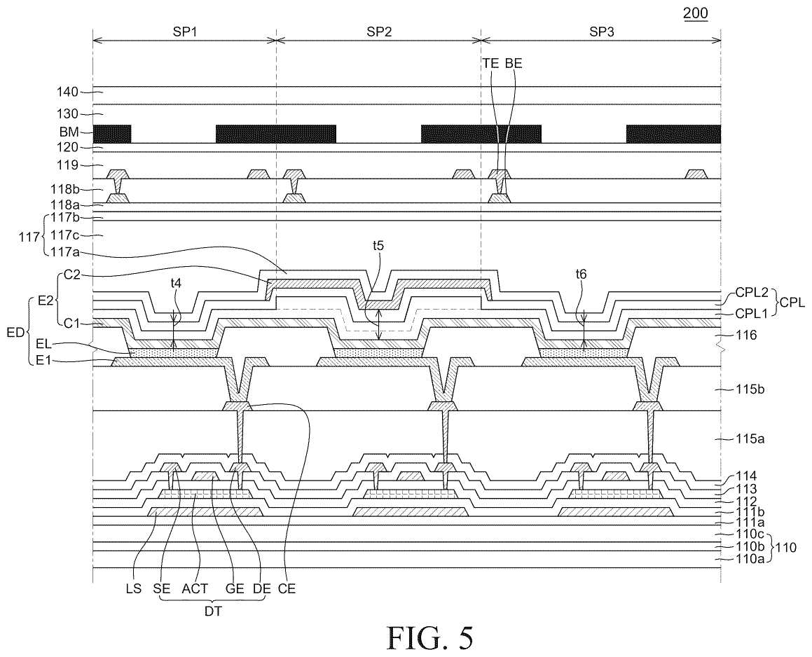

FIG. 5 is a schematic cross-sectional view of a display device according to another embodiment of the present disclosure. A display device 200 of FIG. 5 has the substantially same configuration as the display device 100 of FIGS. 1 to 3, except for a capping layer CPL and a second electrode E2, so that a redundant description will be omitted.

In each sub pixel SP, a light emitting element ED including a first electrode E1, an organic layer EL, and a second electrode E2 may be positioned. For example, the second electrode E2 may be referred to as a cathode. The second electrode E2 may include a first cathode C1 and a second cathode C2 disposed in at least one sub pixel SP among the plurality of sub pixels SP.

A capping layer CPL may be disposed on the first cathode C1. The capping layer CPL may help light emitted from the light emitting layer EL to be efficiently emitted to the outside while protecting the light emitting element ED.

The capping layer CPL may include a first capping layer CPL1 made of an organic material, and a second capping layer CPL2 disposed on the first capping layer CPL1 and made of an inorganic material.

The capping layer CPL may have a different thickness in at least one of the red sub pixel SP1, the green sub pixel SP2, and the blue sub pixel SP3.

The thickness of the capping layer CPL in each of the red sub pixel SP1, the green sub pixel SP2, and the blue sub pixel SP3 may be different by adjusting the thickness of the first capping layer CPL1 made of an organic material. For example, the first capping layer CPL1 made of an organic material is disposed in each of the red sub pixel SP1, the green sub pixel SP2, and the blue sub pixel SP3 to have the same thickness. Thereafter, a mask may be disposed to overlap the red sub pixel SP1 and the blue sub pixel SP3, and a material for forming the first capping layer CPL1 may be additionally applied. Accordingly, the thickness of the first capping layer CPL1 may increase in the green sub pixel SP2 than in the red sub pixel SP1 and the blue sub pixel SP3. Thereafter, the second capping layer CPL2 made of an inorganic material may be disposed on the first capping layer CPL1 with the same thickness.

Referring to FIG. 5, a thickness t5 of the capping layer CPL in the green sub pixel SP2 may be greater than a thickness t4 of the capping layer CPL in the red sub pixel SP1 and greater than a thickness t6 of the capping layer CPL in the blue sub pixel SP3. For example, the thickness t4 of the capping layer CPL in the red sub pixel SP1 and the thickness t6 of the capping layer CPL in the blue sub pixel SP3 may be the same.

In the green sub pixel SP2, the second cathode C2 may be disposed on the capping layer CPL.

In the green sub pixel SP2, the second electrode E2 includes a first cathode C1 and a second cathode C2 and a capping layer CPL is disposed between the first cathode C1 and the second cathode C2, such that resonance may occur in the green sub pixel SP2. Accordingly, reflectance of the green wavelength in the green sub pixel SP2 may be increased. As shown in FIG. 5, the second cathode C2 may include a body portion in the green sub pixel SP2, and end portions in the red sub pixel SP1 and the blue sub pixel SP3. In addition, the end portions of the second cathode C2 may be in contact with a side surface of the second capping layer CPL2. For example, the end portions of the second cathode C2 may be inclined.

The encapsulation unit 117 may be disposed on the light emitting element ED. For example, the encapsulation unit 117 may include a first inorganic encapsulation layer 117a, a second inorganic encapsulation layer 117b, and an organic encapsulation layer 117c disposed between the first inorganic encapsulation layer 117a and the second inorganic encapsulation layer 117b.

In the red sub pixel SP1 and the blue sub pixel SP3, the first inorganic encapsulation layer 117a may be in contact with the capping layer CPL, and in the green sub pixel SP2, the first inorganic encapsulation layer 117a may be in contact with the green light emitting element ED.

In the display device 200 according to another exemplary embodiment of the present disclosure, when the display device 200 does not emit light, the reflectance of the green wavelength, which has a complementary color relationship with the purple color caused by the organic dye layer 130, may be increased to improve the black visibility.

Specifically, the second cathode C2 is further disposed on the first cathode C1 with the capping layer CPL interposed in the green sub pixel SP2, so that when the display device 200 does not emit light, reflectance of the green wavelength due to external light may be increased. Accordingly, when the display device 200 does not emit light, the reflectance of the green wavelength, which has a complementary color relationship with the purple due to the organic dye layer 130, may increase, thereby improving the black visibility.

Further, in the display device 200 according to another exemplary embodiment of the present disclosure, the organic dye layer 130 integrated in the plurality of sub pixels SP is disposed by an application process such as inkjet or photo to reduce the thickness of the display device 200 and reduce process cost and process time by not performing a mask process.

Further, in the display device 200 according to another exemplary embodiment of the present disclosure, the low-temperature black matrix BM and the bank 116 are disposed in the non-light emitting area of the plurality of light emitting elements ED to suppress light emitted from the plurality of light emitting elements ED from being directed to the non-light emitting area of the plurality of light emitting elements ED. Accordingly, even if the polarization layer is not disposed, reflectance in the non-light emitting area of the plurality of light emitting elements ED may be reduced, and light leakage defects may be prevented.

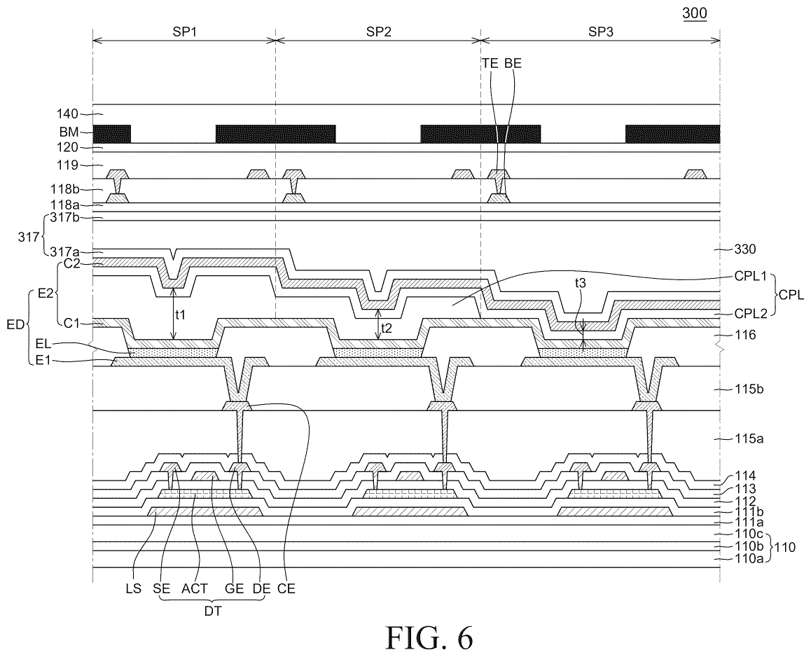

FIG. 6 is a schematic cross-sectional view of a display device according to still another exemplary embodiment of the present disclosure. A display device 300 of FIG. 6 has the substantially same configuration as the display device 100 of FIGS. 1 to 3, except for the encapsulation unit 317 and the organic dye layer 330, so that a redundant description will be omitted.

In each sub pixel SP, a light emitting element ED including a first electrode E1, an organic layer EL, and a second electrode E2 may be positioned.

The encapsulation unit 317 may be disposed to cover the plurality of light emitting elements ED. For example, the encapsulation unit 317 may include a first inorganic encapsulation layer 317a and a second inorganic encapsulation layer 317b on the first inorganic encapsulation layer 317a.

The first inorganic encapsulation layer 317a may be disposed to cover the second electrode E2 and disposed to be most adjacent to the light emitting element ED. The first inorganic encapsulation layer 317a may be formed of an inorganic insulating material on which low-temperature deposition may be performed. For example, the first inorganic encapsulation layer 317a may be made of silicon nitride (SiNx), silicon oxide (SiOx), silicon oxynitride (SiON), or aluminum oxide (Al₂O₃). Since the first inorganic encapsulation layer 317a is deposited in a low temperature atmosphere, it is possible to prevent damage to the light emitting layer EL including an organic material vulnerable to a high temperature atmosphere during the deposition process.

The second inorganic encapsulation layer 317b may be disposed on the first inorganic encapsulation layer 317a.

The second inorganic encapsulation layer 317b may minimize or block the permeation of external moisture or oxygen into the lower portion of the second inorganic encapsulation layer 317b. For example, the second inorganic encapsulation layer 317b may be made of an inorganic insulating material such as silicon nitride (SiNx), silicon oxide (SiOx), silicon oxynitride (SiON), or aluminum oxide (Al₂O₃).

The organic dye layer 330 may be disposed between the first inorganic encapsulation layer 317a and the second inorganic encapsulation layer 317b.

For example, the organic dye layer 330 may include a colorant such as a dye or pigment and a monomer. In addition, the organic dye layer 330 may further include a polymer material in addition to a colorant and a monomer. For example, when the organic dye layer 330 further includes a polymer material, the upper surface of the organic dye layer 330 may be planarized. The polymer material included in the organic dye layer 330 may be a polyimide, epoxy, or acrylic polymer material, but is not limited thereto, and may be used without being limited as long as it is for planarizing the organic dye layer 330.

The organic dye layer 330 may be formed by an application process such as inkjet or photo.

The organic dye layer 330 may be integrally disposed to cover the light emitting area and the non-light emitting area of the plurality of light emitting elements ED. Specifically, the organic dye layer 330 may be integrally formed to correspond to the red sub pixel SP1, the green sub pixel SP2, and the blue sub pixel SP3 to have a wavelength that transmits both red light, green light, and blue light. Accordingly, even though the plurality of light emitting elements ED disposed in each

of the red sub pixel SP1, the green sub pixel SP2, and the blue sub pixel SP3 emits red light, green light, or blue light, the organic dye layer 330 may transmit light emitted from each of the plurality of sub pixels SP.

In addition, the organic dye layer 330 is integrally formed to correspond to the plurality of sub pixels SP, thereby simplifying the manufacturing process and reducing the process cost and the process time compared to the case where the organic dye layer is separately formed for each sub pixel.

In the display device 300 according to still another exemplary embodiment of the present disclosure, when the display device 300 does not emit light, the reflectance of the green wavelength, which has a complementary color relationship with the purple color caused by the organic dye layer 330, may be increased to improve the black visibility.

Further, in the display device 300 according to still another exemplary embodiment of the present disclosure, the organic dye layer 330 integrally formed in the plurality of sub pixels SP is disposed between the first inorganic encapsulation layer 317a and the second inorganic encapsulation layer 317b instead of the organic encapsulation layer, thereby reducing the thickness of the display device 300 and reducing the number of processes.

Further, in the display device 400 according to still another exemplary embodiment of the present disclosure, the low-temperature black matrix BM and the bank 116 are disposed in the non-light emitting area of the plurality of light emitting elements ED to suppress light emitted from the plurality of light emitting elements ED from being directed to the non-light emitting area of the plurality of light emitting elements ED. Accordingly, even if the polarization layer is not disposed, reflectance in the non-light emitting area of the plurality of light emitting elements ED may be reduced, and light leakage defects may be prevented.

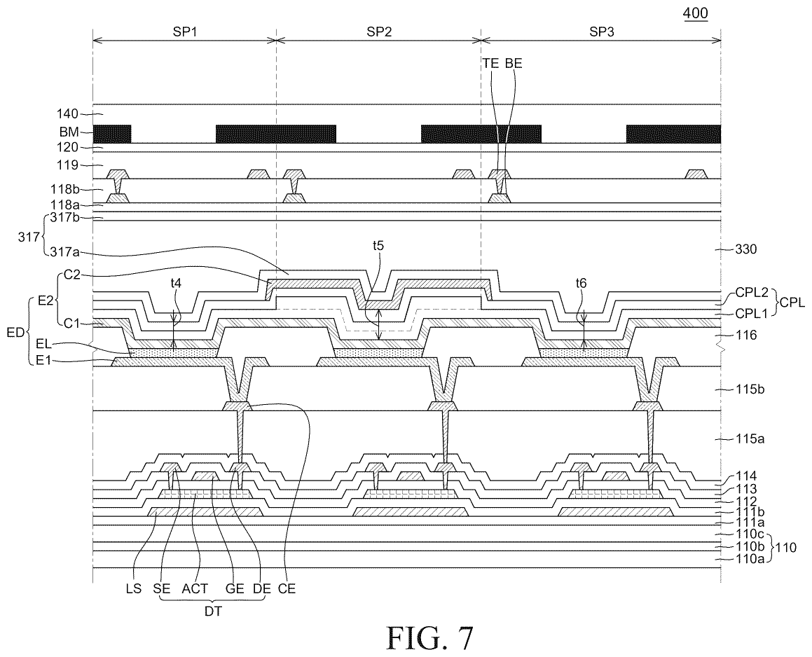

FIG. 7 is a schematic cross-sectional view of a display device according to still another exemplary embodiment of the present disclosure. The display device 400 of FIG. 7 has the substantially same configurations as the display device 200 of FIG. 5 except for the encapsulation unit 317 and the organic dye layer 330, and accordingly, their common features are not described.

In each sub pixel SP, a light emitting element ED including a first electrode E1, an organic layer EL, and a second electrode E2 may be positioned.

The encapsulation unit 317 may be disposed to cover the plurality of light emitting elements ED. For example, the encapsulation unit 317 may include a first inorganic encapsulation layer 317a and a second inorganic encapsulation layer 317b on the first inorganic encapsulation layer 317a.

The first inorganic encapsulation layer 317a may be disposed to cover the second electrode E2 and disposed to be most adjacent to the light emitting element ED. The first inorganic encapsulation layer 317a may be formed of an inorganic insulating material on which low-temperature deposition may be performed. For example, the first inorganic encapsulation layer 317a may be made of silicon nitride (SiNx), silicon oxide (SiOx), silicon oxynitride (SiON), or aluminum oxide (Al₂O₃). Since the first inorganic encapsulation layer 317a is deposited in a low temperature atmosphere, it is possible to prevent damage to the light emitting layer EL including an organic material vulnerable to a high temperature atmosphere during the deposition process.

The second inorganic encapsulation layer 317b may be disposed on the first inorganic encapsulation layer 317a.

The second inorganic encapsulation layer 317b may minimize or block the permeation of external moisture or oxygen into the lower portion of the second inorganic encapsulation layer 317b. For example, the second inorganic encapsulation layer 317b may be made of an inorganic insulating material such as silicon nitride (SiNx), silicon oxide (SiOx), silicon oxynitride (SiON), or aluminum oxide (Al₂O₃).

The organic dye layer 330 may be disposed between the first inorganic encapsulation layer 317a and the second inorganic encapsulation layer 317b.

For example, the organic dye layer 330 may include a colorant such as a dye or pigment and a monomer. In addition, the organic dye layer 330 may further include a polymer material in addition to a colorant and a monomer. For example, when the organic dye layer 330 further includes a polymer material, the upper surface of the organic dye layer 330 may be planarized. The polymer material included in the organic dye layer 330 may be a polyimide, epoxy, or acrylic polymer material, but is not limited thereto, and may be used without being limited as long as it is for planarizing the organic dye layer 330.

The organic dye layer 330 may be formed by an application process such as inkjet or photo.

The organic dye layer 330 may be integrally disposed to cover the light emitting area and the non-light emitting area of the plurality of light emitting elements ED. Specifically, the organic dye layer 330 may be integrally formed to correspond to the red sub pixel SP1, the green sub pixel SP2, and the blue sub pixel SP3 to have a wavelength that transmits both red light, green light, and blue light. Accordingly, even though the plurality of light emitting elements ED disposed in each of the red sub pixel SP1, the green sub pixel SP2, and the blue sub pixel SP3 emits red light, green light, or blue light, the organic dye layer 330 may transmit light emitted from each of the plurality of sub pixels SP.

In addition, the organic dye layer 330 is integrally formed to correspond to the plurality of sub pixels SP, thereby simplifying the manufacturing process and reducing the process cost and the process time compared to the case where the organic dye layer is separately formed for each sub pixel.

In the display device 400 according to still another exemplary embodiment of the present disclosure, when the display device 400 does not emit light, the reflectance of the green wavelength, which has a complementary color relationship with the purple color caused by the organic dye layer 330, may be increased to improve the black visibility.

Further, in the display device 400 according to still another exemplary embodiment of the present disclosure, the organic dye layer 330 integrally formed in the plurality of sub pixels SP is disposed between the first inorganic encapsulation layer 317a and the second inorganic encapsulation layer 317b instead of the organic encapsulation layer, thereby reducing the stacking thickness of the display device 400 and reducing the number of processes.

Further, in the display device 400 according to still another exemplary embodiment of the present disclosure, the low-temperature black matrix BM and the bank 116 are disposed in the non-light emitting area of the plurality of light emitting elements ED to suppress light emitted from the plurality of light emitting elements ED from being directed to the non-light emitting area of the plurality of light emitting elements ED. Accordingly, even if the polarization layer is not disposed, reflectance in the non-light emitting area of the plurality of light emitting elements ED may be reduced, and light leakage defects may be prevented.

The exemplary embodiments of the present disclosure can also be described as follows:
A display device according to an exemplary embodiment of the present disclosure includes a substrate on which a plurality of sub pixels including a first sub pixel, a second sub pixel, and a third sub pixel are defined, a plurality of light emitting elements respectively disposed in the first sub pixel, the second sub pixel and the third sub pixel on the substrate, and comprising a first light emitting element, a second light emitting element, and a third light emitting element including an anode, a light emitting layer, and a first cathode respectively, a capping layer disposed on the first cathode of the first light emitting element, the first cathode of the second light emitting element and the first cathode of the third light emitting element, and having different thicknesses in at least one sub pixel of the plurality of sub pixels, and an organic dye layer disposed on the plurality of light emitting elements, wherein at least one of light emitting element among the plurality of light emitting elements further comprises a second cathode disposed on the first cathode with the capping layer interposed therebetween.

The first sub pixel may be a red sub pixel, the second sub pixel may be a green sub pixel, and the third sub pixel may be a blue sub pixel, and the second cathode may be disposed on the first cathode of the second light emitting element with the capping layer interposed therebetween in the second light emitting element disposed in the second sub pixel.

The first light emitting element may further include a second cathode disposed on the first cathode of the first light emitting element with the capping layer interposed therebetween, and the third light emitting element may further include a second cathode disposed on the first cathode of the third light emitting element with the capping layer interposed therebetween.

A thickness of the capping layer in the first sub pixel may be greater than a thickness of the capping layer in the second sub pixel, and a thickness of the capping layer in the second sub pixel may be greater than a thickness of the capping layer in the third sub pixel.

The capping layer may further include a first capping layer made of an organic material and a second capping layer disposed on the first capping layer and made of an inorganic material.

The display device may further include an encapsulation unit disposed on the plurality of light emitting elements and including a first inorganic encapsulation layer, an organic encapsulation layer on the first inorganic encapsulation layer, and a second inorganic encapsulation layer on the organic encapsulation layer, a touch sensing part on the encapsulation unit, and a black matrix disposed in a non-light emitting area of the plurality of light emitting elements on the touch sensing unit, the organic dye layer may be disposed to cover the black matrix.

The display device may further include an encapsulation unit which is disposed on the plurality of light emitting elements and includes a first inorganic encapsulation layer and a second inorganic encapsulation layer on the first inorganic encapsulation layer, and the organic dye layer may be disposed between the first inorganic encapsulation layer and the second inorganic encapsulation layer.

The thickness of the capping layer in the second sub pixel may be greater than the thickness of the capping layer in each of the first sub pixel and the third sub pixel.

The capping layer may further include a first capping layer made of an organic material and a second capping layer disposed on the first capping layer and made of an inorganic material.

The display device may further comprise an encapsulation unit disposed on the plurality of light emitting elements and the capping layer, the encapsulation unit including a first inorganic encapsulation layer and a second inorganic encapsulation layer on the first inorganic encapsulation layer, the first inorganic encapsulation layer may be in contact with the capping layer in the first sub pixel and the third sub pixel, and the first inorganic encapsulation layer may be in contact with the second light emitting element in the second sub pixel.

The display device may further include a touch sensing unit on the encapsulation unit, and a black matrix disposed in a non-light emitting area of the light emitting element on the touch sensing unit, the encapsulation unit may further include an organic encapsulation layer disposed between the first inorganic encapsulation layer and the second inorganic encapsulation layer, and the organic dye layer may be disposed to cover the black matrix.

The organic dye layer may be disposed between the first inorganic encapsulation layer and the second inorganic encapsulation layer.

The first capping layer and the second capping layer may have different refractive indexes.

The organic dye layer may be integrally formed to correspond to the plurality of sub pixels.

A thickness of the capping layer in the first sub pixel and the third sub pixel may be disposed such that extinction interference occurs.

The black matrix may be made of a material that is processed at a temperature of 100° C. or less.

The display device may further include an organic insulating layer disposed to cover the organic dye layer.

A thickness of the capping layer in the first sub pixel and a thickness of the capping layer in the third sub pixel may be the same.

The first capping layer may be only disposed in the first sub pixel and the second sub pixel.

The second capping layer may be in contact with an end portion of the first capping layer.

The second cathode may include a body portion in the second sub pixel, and end portions in the first sub pixel and the third sub pixel, and the end portions of the second cathode may be in contact with a side surface of the second capping layer.

According to another aspect of the present disclosure, a display device includes a substrate on which a plurality of sub pixels including a first sub pixel, a second sub pixel, and a third sub pixel is disposed, a plurality of light emitting elements including a first light emitting element, a second light emitting element and a third light emitting element, the first light emitting element, the second light emitting element and the third light emitting element being respectively disposed in the first sub pixel, the second sub pixel, and the third sub pixel on the substrate, and each of the first light emitting element, the second light emitting element and the third light emitting element including an anode, a light emitting layer, and a first cathode, and an organic dye layer disposed on the plurality of light emitting elements, a thickness of a capping layer disposed in any one of the plurality of sub pixels is greater than a thickness of the capping layer disposed in the other of the plurality of sub pixels.

A thickness of the capping layer in the second sub pixel may be greater than a thickness of the capping layer in the third sub pixel.

The first sub pixel may be a red sub pixel, the second sub pixel may be a green sub pixel, and the third sub pixel may be a blue sub pixel, and the second light emitting element disposed in the second sub pixel may further include a second cathode disposed on the first cathode of the second light emitting element with a capping layer interposed therebetween.

The display device may further comprise an encapsulation unit disposed on the plurality of light emitting elements and including a first inorganic encapsulation layer and a second inorganic encapsulation layer on the first inorganic encapsulation layer, the organic dye layer may be disposed between the first inorganic encapsulation layer and the second inorganic encapsulation layer.

The first light emitting element may further include a second cathode disposed on the first cathode of the first light emitting element with a capping layer interposed therebetween, and the third light emitting element may further include a second cathode disposed on the first cathode of the third light emitting element with a capping layer interposed therebetween.

A thickness of the capping layer in the first sub pixel may be greater than a thickness of the capping layer in the second sub pixel.

A thickness of the capping layer in the second sub pixel may be greater than a thickness of the capping layer in the first sub pixel.

The display device may further include an encapsulation unit which is disposed on the plurality of light emitting elements and includes a first inorganic encapsulation layer, an organic encapsulation layer on the first inorganic encapsulation layer, and a second inorganic encapsulation layer on the organic encapsulation layer, a touch sensing unit on the encapsulation unit, and a black matrix disposed in a non-light emitting area of the plurality of light emitting elements on the touch sensing unit, the organic dye layer may be disposed to cover the black matrix.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate on which a plurality of sub pixels including a first sub pixel, a second sub pixel, and a third sub pixel are defined;
a plurality of light emitting elements respectively disposed in the first sub pixel, the second sub pixel and the third sub pixel on the substrate, and comprising a first light emitting element, a second light emitting element, and a third light emitting element including an anode, a light emitting layer, and a first cathode respectively;
a capping layer disposed on the first cathode of the first light emitting element, the first cathode of the second light emitting element and the first cathode of the third light emitting element, and having different thicknesses in at least one sub pixel of the plurality of sub pixels; and
an organic dye layer disposed on the plurality of light emitting elements,
wherein at least one of light emitting element among the plurality of light emitting elements further comprises a second cathode disposed on the first cathode with the capping layer interposed therebetween.

2. The display device according to claim 1, wherein the first sub pixel is a red sub pixel, the second sub pixel is a green sub pixel, and the third sub pixel is a blue sub pixel, and
the second cathode is disposed on the first cathode of the second light emitting element with the capping layer interposed therebetween in the second light emitting element disposed in the second sub pixel.

3. The display device according to claim 2, wherein the first light emitting element further includes a second cathode disposed on the first cathode of the first light emitting element with the capping layer interposed therebetween, and
the third light emitting element further includes a second cathode disposed on the first cathode of the third light emitting element with the capping layer interposed therebetween.

4. The display device of claim 3, wherein a thickness of the capping layer in the first sub pixel is greater than a thickness of the capping layer in the second sub pixel, and
a thickness of the capping layer in the second sub pixel is greater than a thickness of the capping layer in the third sub pixel.

5. The display device according to claim 4, wherein the capping layer further comprises a first capping layer made of an organic material and a second capping layer disposed on the first capping layer and made of an inorganic material.

6. The display device according to claim 4, further comprising:
an encapsulation unit which is disposed on the plurality of light emitting elements and includes a first inorganic encapsulation layer, an organic encapsulation layer on the first inorganic encapsulation layer, and a second inorganic encapsulation layer on the organic encapsulation layer;
a touch sensing unit on the encapsulation unit; and
a black matrix disposed in a non-light emitting area of the plurality of light emitting elements on the touch sensing unit,
wherein the organic dye layer is disposed to cover the black matrix.

7. The display device according to claim 4, further comprising:
an encapsulation unit which is disposed on the plurality of light emitting elements and includes a first inorganic encapsulation layer and a second inorganic encapsulation layer on the first inorganic encapsulation layer,
wherein the organic dye layer is disposed between the first inorganic encapsulation layer and the second inorganic encapsulation layer.

8. The display device of claim 2, wherein a thickness of the capping layer in the second sub pixel is greater than a thickness of the capping layer in each of the first sub pixel and the third sub pixel.

9. The display device according to claim 8, wherein the capping layer further comprises a first capping layer made of an organic material and a second capping layer disposed on the first capping layer and made of an inorganic material.

10. The display device of claim 9, further comprising:
an encapsulation unit disposed on the plurality of light emitting elements and the capping layer and including a first inorganic encapsulation layer and a second inorganic encapsulation layer on the first inorganic encapsulation layer,
wherein the first inorganic encapsulation layer is in contact with the capping layer in the first sub pixel and the third sub pixel, and
the first inorganic encapsulation layer is in contact with the second light emitting element in the second sub pixel.

11. The display device according to claim 10, further comprising:
a touch sensing unit on the encapsulation unit; and
a black matrix disposed in a non-light emitting area of the light emitting element on the touch sensing unit,
wherein the encapsulation unit further includes an organic encapsulation layer disposed between the first inorganic encapsulation layer and the second inorganic encapsulation layer, and
the organic dye layer is disposed to cover the black matrix.

12. The display device according to claim 10, wherein the organic dye layer is disposed between the first inorganic encapsulation layer and the second inorganic encapsulation layer.

13. The display device according to claim 5, wherein the first capping layer and the second capping layer have different refractive indexes.

14. The display device according to claim 5, wherein the first capping layer is only disposed in the first sub pixel and the second sub pixel, and
the second capping layer is in contact with an end portion of the first capping layer.

15. A display device, comprising:
a substrate on which a plurality of sub pixels including a first sub pixel, a second sub pixel, and a third sub pixel is disposed;
a plurality of light emitting elements including a first light emitting element, a second light emitting element and a third light emitting element, the first light emitting element, the second light emitting element and the third light emitting element being respectively disposed in the first sub pixel, the second sub pixel, and the third sub pixel on the substrate, and each of the first light emitting element, the second light emitting element and the third light emitting element including an anode, a light emitting layer, and a first cathode; and
an organic dye layer disposed on the plurality of light emitting elements,
wherein a thickness of a capping layer disposed in any one of the plurality of sub pixels is greater than a thickness of the capping layer disposed in the other of the plurality of sub pixels.

16. The display device of claim 15, wherein a thickness of the capping layer in the second sub pixel is greater than a thickness of the capping layer in the third sub pixel.

17. The display device of claim 16, wherein the first sub pixel is a red sub pixel, the second sub pixel is a green sub pixel, and the third sub pixel is a blue sub pixel, and
the second light emitting element disposed in the second sub pixel further includes a second cathode disposed on the first cathode of the second light emitting element with the capping layer interposed therebetween.

18. The display device of claim 17, further comprising:
an encapsulation unit disposed on the plurality of light emitting elements and including a first inorganic encapsulation layer and a second inorganic encapsulation layer on the first inorganic encapsulation layer,
wherein the organic dye layer is disposed between the first inorganic encapsulation layer and the second inorganic encapsulation layer.

19. The display device according to claim 18, wherein the first light emitting element further includes a second cathode disposed on the first cathode of the first light emitting element with the capping layer interposed therebetween, and
the third light emitting element further includes a second cathode disposed on the first cathode of the third light emitting element with the capping layer interposed therebetween.

20. The display device of claim 19, wherein a thickness of the capping layer in the first sub pixel is greater than a thickness of the capping layer in the second sub pixel, and a thickness of the capping layer in the second sub pixel is greater than a thickness of the capping layer in the first sub pixel.

21. The display device of claim 17, further comprising:
an encapsulation unit which is disposed on the plurality of light emitting elements and includes a first inorganic encapsulation layer, an organic encapsulation layer on the first inorganic encapsulation layer, and a second inorganic encapsulation layer on the organic encapsulation layer;
a touch sensing unit on the encapsulation unit; and
a black matrix disposed in a non-light emitting area of the plurality of light emitting elements on the touch sensing unit,
wherein the organic dye layer is disposed to cover the black matrix.
